(19) United States
(12) Patent Application Publication
(10) Pub. No.: US 2010/0037816 A1
(43) Pub. Date: Feb. 18, 2010

(54) CRYSTAL GROWING SYSTEM HAVING MULTIPLE CRUCIBLES AND USING A TEMPERATURE GRADIENT METHOD

(76) Inventor: Youbao Wan, Zhejiang (CN)

Correspondence Address: DON W. BULSON (GRCO);RENNER, OTTO, BOISSELLE & SKLAR, LLP, 1621 EUCLID AVENUE, 19TH FLOOR, CLEVELAND, OH, 44115, US

(21) Appl. No.: 12/448,654

(22) PCT Filed: Dec. 27, 2007
(86) PCT No.: PCT/CN2007/003854

§ 371 Date: Jun. 29, 2009

(30) Foreign Application Priority Data
Dec. 29, 2006 (CN) 200610148319.4

(51) Int. Cl. C30B 11/00

(52) U.S. Cl. 117/74; 117/206; 117/73

(57) ABSTRACT

A multiple crucible crystal growing system using a temperature gradient method is disclosed. The system comprises a crystal furnace, a plurality of crucibles, and an elevating device, wherein the furnace includes a furnace body, a heater, and a hearth, wherein the furnace body from outer to inner includes an outer shell, a fiber insulation layer, an insulation brick layer, and a refractory layer. The height of the refractory layer is ⅔-⅚ of the height of the hearth, and the heater is located at ¼-½ of the height of the hearth. The hearth is in rectangular shape and able to hold multiple crucibles to grow crystals simultaneously. The present invention ensures doping concentration and uniformity. Therefore, it can be widely applied in the area of crystal growth.

### CROSS REFERENCE TO RELATED APPLICATIONS

This is a 35 USC §371 application of the International Application No. PCT/CN2007/003854, filed Dec. 27, 2007, that claims priority to the Chinese Patent Application No. 200610148319.4, filed Dec. 29, 2006.

### FIELD OF THE INVENTION

The present invention relates to the crystal growing area, and more particularly to a crystal growing system having multiple crucibles and using a temperature gradient method.

### BACKGROUND OF THE INVENTION

Chinese Patent No. 200420082546.8 describes a crystal growing device that can effectively grow a single crystal using a dual heating temperature gradient method. Similar to a traditional temperature gradient method, during the crystal growing process the heater is at a partial height of the crucible, and gradual crystal growth is achieved through moving the heater at a proper speed. This type of method is effective in growing a single crystal, but cannot be used to realize the growth of multiple crystals simultaneously.

In the prior art multiple crucible crystal growing technologies, a crystal growing system generally employs the Bridgeman method. This type of system elongates the hearth of the furnace in one direction, so that the hearth can house multiple growing crystals simultaneously. The near rectangular temperature field formed in the elongated direction under the condition has achieved initial success of growing lead tungstate crystal that has a square outer appearance. In this type of Bridgeman crystal growing system, the high temperature zone in the hearth is usually the whole chamber area above the crystal growing point, and the crystal growing material and doping agent are in molten state. Let's use growing ion doped lead tungstate as an example. When growing a crystal with a doping material such as La₂O₃ that has high melting point and low volatility, the space above the solid part, that is preformed or formed due to volume contraction from growing the multiple crystal raw material into the single crystal product, has no apparent effect on crystal growth. On the other hand, when growing with a doping material that has low melting point and high volatility, such as PbF₂ with melting point at 850° C., the doping agent can significantly evaporate into the space above, which is ever expanding in the crystal growing process. The significant evaporation makes uniform doping almost impossible. Meanwhile the effect of the off chemical ratio evaporation of components PbO and W₂O₃ on crystal growing cannot be overlooked.

Chinese invention Patent Application No. 200310109498.4, A Method of Producing Fluorine Ion Doped Lead Tungstate Scintillation Crystal, attempts to resolve the issue of growing ion doped crystal with highly volatile doping agent. It discloses a technology that involves placing a grown lead tungstate crystal in a closed PbF₂ atmosphere to cause high temperature dissipation, relying on the high temperature dissipation property to force PbWO₄ crystal to be doped and change its properties. Using the technology lead tungstate crystal can be partially doped with PbF₂. However, particle dissipation is very hard to happen in solid state. So as depth increases dissipation rate drops significantly, and the PbF₂ concentration is getting lower and its distribution is not uniform. Therefore, the technology of growing PbF₂:PbWO₄ crystal has two hard to overcome difficulties: First, there is no guarantee that the doped crystal will get required doping concentration; Secondly, PbF₂ doping concentration in crystal is not uniform. In conclusion, it's hard to grow good quality PbF₂:PbWO₄ crystal using the method.

### SUMMARY OF THE INVENTION

The main technical problem the present invention is trying to resolve is to provide a crystal growing system having multiple crucibles and using a temperature gradient method to guarantee doping concentration and its uniformity.

The technical scheme of the present invention is a crystal growing system having multiple crucibles using a temperature gradient method comprising a crystal furnace, a plurality of crucibles, and an elevating device, wherein the furnace includes a furnace body, a hearth, and a heater, wherein the furnace body from outer to inner includes an outer shell, a fiber insulation layer, an insulation brick layer, and a refractory layer. The height of the refractory layer is ⅔-⅚ of the height of the hearth; and the heater is located at ¼-½ of the height of the hearth. The hearth is rectangular shaped, able to house multiple crucibles each growing a crystal simultaneously.

When applying the present invention in practice, because the heater is located ¼-½ of the hearth height and the refractory layer height is only ⅔-⅚ of the height of the hearth, there is leftover space to accelerate heat dissipation, thus forming four temperature zones along the central vertical axis of the crystal hearth. From top to bottom, the 4 zones are the 1^{st} temperature zone, the 2^{nd} temperature zone, the 3^{rd} temperature zone, and the 4^{th} temperature zone, respectively. When the crucibles are placed in the hearth to grow crystals, the raw material in the 1^{st} temperature zone is not melted; and the raw material in the 2^{nd} temperature zone is being melted. The boundary of the 1^{st} temperature zone and the 2^{nd} temperature zone is corresponding to the melting point of the raw material. Temperature in the 3^{rd} temperature zone is below the melting point, and material there is being crystallized. Temperature at the boundary between the 2^{nd} temperature zone and the 3^{rd} temperature zone is the crystallization temperature. Temperature gradient in the 3^{rd} temperature zone is big, able to provide the driving force for crystallization to happen. At the bottom is the 4^{th} temperature zone that has fully grown crystal. In this temperature zone temperature is getting ever lower and all the way reaching room temperature to the very bottom. At the beginning of crystal growing, the 4^{th} temperature zone at the bottom is corresponding to the seed crystal and the grown crystal; the 3^{rd} temperature zone is corresponding to seed crystal that is close to the melt; the 2^{nd} temperature zone corresponding to the melt; the boundary between the 2^{nd} and the 3^{rd} temperature zones is the liquid-to-solid interface of the growing crystal; and the 1^{st} temperature zone corresponding to the multi crystal raw material that is not melted. The 2^{nd} temperature zone that is corresponding to the melt is small in height. That is, only a local region in the crucible is in molten state. During the crystal growing process, the part of material that is at the top of the crucible and not melted is in solid state, and is in tight contact with the crucible wall, thus preventing or impeding the evaporation of volatile gas from the melt below. In this way, a solid seal is formed to almost eliminate the space for volatile gas and to increase its saturated pressure. Therefore, the volatile gas will not be evaporated into the space above in significant quantity. And the melt is protected so that severe off chemical ratio evaporation of the components won't happen and the component composition in the melt will not deviate from the ratio required for crystal growing.

When applied to grow crystal, the present invention can achieve a stable temperature field, so crystal can grow in a table state. However, in the present invention the crucibles only move up and down slowly during crystal growing, and the slow movement does not contribute to forced convection in the melt. Particle transfer is realized through natural convection only, and the transfer rate is slow. Therefore, the present invention is suitable for growing ion doped crystal when the effective segregation coefficient of doping agent ion is similar to that of the base material ion.

In the present system, the rectangular hearth can simultaneously hold many and even up to tens of growing crystals, realizing the object of growing multiple crystals in multiple crucibles simultaneously. The heater located at the hearth wall can satisfy the heating requirement of crystal growing. Similar to the multiple crucible Bridgeman system, the near rectangular and asymmetric temperature field along the elongated axis is suitable for growing crystals having square outer appearance, but not beneficial for growing round crystals. In the whole growing process, because the melt and the crystal in the crucibles are not moving relative to each other, forced convection is not happening and particle transfer efficiency is low. This is not beneficial for growing a crystal that has significant difference between the component ion effective segregation coefficients. However, the whole crystal growing process is progressing under a very calm condition, beneficial to the integrity of the growing crystal. Therefore, the system is a very good choice for those crystals that have low requirements for particle transfer and have small difference between component ion effective segregation coefficients.

The furnace structure in the present invention includes a fixed position heater, and the movable parts are the crucibles, where crystals are being grown, that are attached to the movable elevating device. Therefore, the temperature field in the hearth is very stable. Compared to the traditional temperature gradient growing system having a movable heater, the present system provide not only more hearth space to hold more crucibles for simultaneously growing multiple crystals, but a relatively stable temperature field that is beneficial to crystal growth.

The present invention has the following benefits: In practical application of growing crystal, part of the raw material in a crucible is melted, and the upper part of the raw material in the crucible that is not melted stays solid and forms a tight contact with the crucible wall to prevent or impede the evaporation of volatile gas from the melt below. A block seal is formed to protect the melt so that severe off chemical ratio evaporation of melt component ions will not happen and the component ions in the melt will not deviate from the component ratio required for crystal growth. Therefore, the system is suitable for growing ion doped crystal not only with highly volatile doping agent but also with non volatile doping agent.

### BRIEF DESCRIPTION OF THE DRAWINGS

FIG. 1 is a structural schematic of the present invention.

FIG. 2 is the partial view of crucible and the elevating device.

### DETAILED DESCRIPTION OF THE INVENTION

The following explanation is in combination with the drawings.

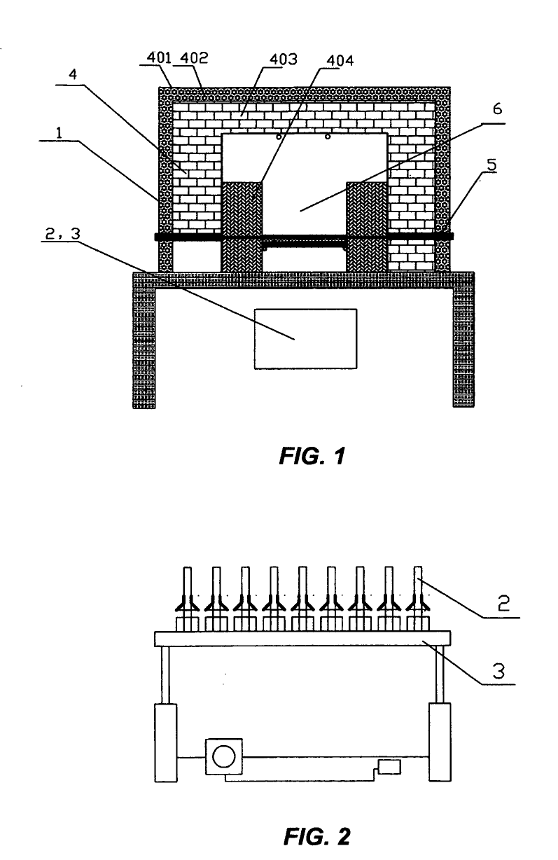

As shown in FIG. 1 and FIG. 2, the multiple crucible crystal growing system using a temperature gradient method includes a crystal furnace 1, a plurality of crucibles 2 that are connected to an elevating device 3. The crucible furnace 1 includes a furnace body 4, a heater 5, and a hearth 6. From outer to inner, the furnace body 4 includes an outer shell 401, a fiber insulation layer 402, an insulation brick layer 403, and a refractory layer 404. The height of the refractory layer 404 is about ⅔ of the height of the hearth 6. The heater is located at about ¼ height of the hearth 6. The height of the refractory layer 404 in the hearth can also be about ¾ or about ⅚ of the height of the hearth. And the location of the heater can be about ⅜ or about ½ of the hearth height. To satisfy growing different crystals and ion doped crystals, the heater can be replaced according to the different crystal melting temperatures and crystallization temperatures. Due to the complexity of temperature variation in the hearth, the present system can be equipped with a temperature control system according to the requirements of growing crystal in practical application.

The present crystal growing system form the characteristics of temperature gradient by locating the heater at about the bottom of the hearth to generate a temperature higher than the crystal melting point and form a local high temperature zone. The upper part of the hearth does not have the refractory layer. The extra space combined with less insulation material at the upper part of the hearth increases heat dissipation, ensuring the formation of a lower temperature zone in the upper chamber with temperature below the crystal melting point. This is beneficial to the formation of a temperature gradient in the hearth. The temperature gradient ensures that the upper part of the raw material in the crucible stays in pre-solidified state so as to limit evaporation of the volatile component in the melt below. The fixed position of the heater ensures the present temperature gradient system to have more stable temperature field than that of the prior art temperature gradient system that relies on moving the heater to grow crystal. Therefore, the present system is beneficial to the realization of stable crystal growth. Meanwhile, the rectangular space in the hearth can hold multiple crucibles simultaneously to achieve growing multiple crystals the same time. The present system can satisfy growing crystals with volatile components in a lab condition. It can also be used in mass production of ion doped crystals. Therefore, the present system is especially suitable for small batch or mass production of ion doped crystals or crystals that have volatile component that have similar component ion effective segregation coefficients. It is especially suitable to growing crystals with square outer appearance.

It is understood that the above-described invention is merely illustrative of the possible specific embodiments which may represent principles of the present invention. Other arrangements may readily be devised in accordance with these principles by those skilled in the art without departing from the scope and spirit of the invention.

1. (canceled)

2. (canceled)

3. A crystal growing system having a crystal furnace wherein the crystal furnace includes an outer shell, a fiber insulation layer, an insulation brick layer, and a hearth with an inner end and an open end, comprising:
a plurality of crucibles capable of moving in and out of the hearth of the crystal furnace from the open end, each crucible capable of growing a crystal inside;
an elevating device capable of moving back and forth in a direction, the elevating device is connected to and carries the plurality of crucibles;
a refractory layer forming the wall the hearth, the refractory layer covering partial height of the hearth from the open end; and
a heater located in the hearth to heat up the crucibles, the heater is affixed to the crystal furnace at a position close to the open end of the hearth.

4. A crystal growing system as recited in claim 3 wherein:
the refractory layer covers ⅔-⅚ of the height of the hearth from the open end.

5. A crystal growing system as recited in claim 3 wherein:
the heater is located at ¼-½ of the height of the hearth from the open end.

6. A crystal growing system as recited in claim 3 wherein:
the heater can be replaced according to heating requirements.

7. A crystal growing system as recited in claim 3 wherein:
the hearth has a near rectangular cross section.

8. A method of growing a plurality of crystals simultaneously in a crystal furnace having a furnace body and a hearth with an inner end and an open end, wherein the furnace body includes an outer shell, a fiber insulation layer, and an insulation brick layer, comprising:
forming a refractory layer covering the hearth wall from the open end to a partial height of the hearth;
providing a plurality of crucibles each capable of growing a crystal inside, the plurality of crucibles at a position inside the hearth and capable of moving out of the hearth from the open end;
heating the plurality of crucibles using a heater affixed to the crystal furnace, wherein the heater is located inside the hearth close to the open end; and
moving the plurality of crucibles slowing out of the hearth from the open end using an elevating device.

9. A crystal growing method as recited in claim 8 wherein:
the refractory layer covers ⅔-⅚ of the height of the hearth from the open end.

10. A crystal growing method as recited in claim 8 wherein:
the heater is located at ¼-½ of the height of the hearth from the open end.

11. A crystal growing method as recited in claim 8 wherein:
the heater can be replaced according to heating requirements.

12. A crystal growing method as recited in claim 8 wherein:
the hearth has a rectangular cross section.

13. A method of growing a plurality of crystals simultaneously in a crystal furnace having a furnace body and a near rectangular shaped hearth with an inner end and an open end, wherein the furnace body includes an outer shell, a fiber insulation layer, and an insulation brick layer, comprising:
placing a crystal growing material in a plurality of crucibles, wherein the plurality of crucibles are placed at a position inside the hearth and are capable of moving out of the hearth from the open end;
forming a temperature field in the crucibles from low temperature to high temperature to low temperature starting from the inner end of the hearth to the open end of hearth and to outside of the hearth, wherein the high temperature zone in the crucibles is formed by a heater attached to the furnace body and located inside the hearth close to the open end wherein the temperature in the high temperature zone is higher than the melting point of the crystal growing material, and wherein the low temperature zone in the crucibles at the inner end of the hearth is formed due to the open space at the inner end of the hearth and a refractory layer that partially covers the hearth wall from the open end and does not cover the inner end of the hearth wall; and
growing a plurality of crystals simultaneously by moving the plurality of crucibles slowing out of the hearth using an elevating device.
